(19) United States
(12) Patent Application Publication
(10) Pub. No.: US 2021/0231824 A1
(43) Pub. Date: Jul. 29, 2021

(54) Metal Detector

(71) Applicant: Minelab Electronics Pty. Limited, Mawson Lakes (AU)

(72) Inventors: Ruifeng Huang, Mawson Lakes (AU); Eng Leng Mah, Mawson Lakes (AU)

(21) Appl. No.: 17/160,584

(22) Filed: Jan. 28, 2021

(30) Foreign Application Priority Data
Jan. 29, 2020 (AU) 2020900234

(51) Int. Cl. G01V 3/10

(52) U.S. Cl. CPC G01V 3/104

(57) ABSTRACT

A method to detect a target in a soil using a metal detector, the method including transmitting a transmit magnetic field based on a transmit signal using a transmitter; receiving a receive magnetic field due to the transmit magnetic field using a receiver; producing a receive signal based on the receive magnetic field; processing the receive signal to produce a movement signal which is sensitive to a movement of a sensor head of the metal detector relative to the Earth's magnetic field; and updating operating parameters of the metal detector based on the movement signal.

### CROSS-REFERENCE TO RELATED APPLICATION

This application claims priority to Australian Patent Application No. 2020900234 filed Jan. 29, 2020, the disclosure of which is hereby incorporated by reference in its entirety.

### BACKGROUND OF THE INVENTION

### Technical Field

The present disclosure relates to a metal detector.

### Description of Related Art

The general forms of most metal detectors which interrogate soil are either handheld battery operated units, conveyor-mounted units, or vehicle-mounted units. Examples of handheld products include detectors used to locate gold, explosive land mines or ordnance, coins and treasure. Examples of conveyor-mounted units include fine gold detectors in ore mining operations, and examples of a vehicle-mounted unit include a unit to locate buried land mines.

These metal detectors usually, but not necessarily, consist of transmit electronics generating a repeating transmit signal cycle of a fundamental period, which is applied to an inductor, for example a transmit coil, which transmits a resulting varying magnetic field, sometimes referred to as a transmit magnetic field.

These metal detectors may also contain receive electronics that processes a receive signal from a measured receive magnetic field, during one or more receive periods during the repeating transmit signal cycle, to produce an indicator output signal, the indicator output signal at least indicating the presence of at least a metal target within the influence of the transmit magnetic field.

During the processing of the receive signal, the receive signal is either sampled, or demodulated, to produce one or more target channels, the one or more target channels may be further processed to produce the indicator output signal.

During the detection process to detect a target in a soil, it may be useful to detect the coil movement to optimize the performance of a metal detector by updating the operating parameters of the metal detector based on the coil movement. Known techniques include use of accelerometers attached to the metal detector to detect the coil movement. The present disclosure offers an alternative to detect the coil movement.

### SUMMARY OF THE INVENTION

According to a first aspect of the present disclosure, there is provided a method to detect a target in a soil using a metal detector, the method comprising: transmitting a transmit magnetic field based on a transmit signal using a transmitter; receiving a receive magnetic field due to the transmit magnetic field using a receiver; producing a receive signal based on the receive magnetic field; processing the receive signal to produce a movement signal which is sensitive to a movement of a sensor head of the metal detector relative to the Earth's magnetic field; and updating operating parameters of the metal detector based on the movement signal.

In one form, the movement signal is produced by demodulating the receive signal to produce a Direct Current (DC) or quasi DC channel that is sensitive to the movement of the sensor head relative to the Earth's magnetic field. In one form, the movement signal is also dependent on a ground channel produced by demodulating the receive signal.

In one form, the receive signal comprises an induced signal due to the movement of the sensor head relative to the Earth's magnetic field.

In one form, the operating parameters comprise one or more of properties of the transmit signal or one or more of properties parameters used to process the receive signal, or both. In one form, the properties of the transmit signal comprises one or more of timings, amplitudes, frequency and phase of the transmit signal. In one form, the parameters used to process the receive signal comprises one or more of demodulation parameters and models for processing the receive signal.

In one form, the step of updating the operating parameters is performed automatically without user's intervention. In one form, the step of updating the operating parameters requires a prior approval of a user of the metal detector.

According to another aspect of the present disclosure, there is provided a non-transitory computer readable medium including instructions to perform the steps of the first aspect.

According to another aspect of the present disclosure, there is provided a metal detector to detect a target in a soil, the metal detector comprising: a transmitter for transmitting a transmit magnetic field based on a transmit signal; a receiver for receiving a receive magnetic field due to the transmit magnetic field; a processor for producing a receive signal based on the receive magnetic field; and for processing the receive signal to produce a movement signal which is sensitive to a movement of a sensor head of the metal detector relative to the Earth's magnetic field; and for updating operating parameters of the metal detector based on the movement signal.

### BRIEF DESCRIPTION OF THE DRAWINGS

Embodiments of the present disclosure will be discussed with reference to the accompanying drawings wherein:

FIG. 1 shows responses of a B channel which can be a direct current (DC) channel or quasi DC channel for different speeds in both time domain and frequency domain;

FIG. 2 shows a typical demodulated B channel response of knocking a coil against a hard object, e.g. rock, tree, ground surface, etc., in both time domain and frequency domain;

FIG. 3 shows steps involved in a general form of one embodiment;

FIG. 4 shows variations in the B channel and Ground channel (G channel) due to the movement of the sensor head of the metal detector; and

FIG. 5 shows exemplary demodulation functions for a B channel and a G channel with respect to a transmit magnetic field.

### DESCRIPTION OF THE INVENTION

Metal detectors such as handheld metal detectors typically have a search coil within a sensor head that is swept over ground to look for buried targets. Metal detectors usually utilize analogue or digital signal processing techniques to separate desirable target responses from undesirable ground or electromagnetic interference (EMI) responses. The techniques commonly include low pass filters, high pass filters, band pass filters, ground balance, discrimination and adjustable detection threshold, etc.

Majorities of the techniques are susceptible to the motion of the coil, and may be optimized if the sweep speed of the coil is known. Alternatively, those techniques may only be triggered if coil motion is detected.

For example, some modern metal detectors have self-adjusting detection threshold which may be adjusted automatically based on the noise level of their detection channel. A signal in the detection channel but below a detection threshold may be ignored to avoid overwhelming false alarms. In other words, when the noise level is high, the detection threshold is increased to reduce false alarms caused by the noise. On the other hand, when the noise level is low, the detection threshold is reduced, so that the metal detector becomes more sensitive. Normally, a signal in the detection channel is high-pass filtered, thus the signal is very small when the coil is stationary. Performing self-adjustment when the coil is stationary would then create an issue in that stationary coil would lead to very low self-adjusting detection threshold and result in a large false alarm rate which could last for a while even after coil sweep is resumed, as the system would take a while to self-adjust. Stopping self-adjustment of detection threshold when coil is stationary would avoid the problem. Alternatively, self-adjustment speed of detection threshold may be kept slow unless coil motion is detected.

In another example, tracking ground balance is paused or set to slow speed in tracking ground balance unless a coil motion is detected. This may avoid a drift of an angle of tracking ground balance when coil is stationary, which may cause a high false alarm rate that may last for a while even after coil sweep is resumed (i.e. the coil is no longer stationary). Meanwhile, the tracking speed may be further adjusted based on the ground channel (G channel). For example, a low tracking speed may be more suitable on “hot” ground (moderately to highly mineralised ground) to avoid tracking out small targets.

In another example, the transmitting circuit of a metal detector may be turned off to save power if the coil of the metal detector is not moving for a certain period of time (say 10 second or 1 minute etc.), and be turned on as soon as a coil motion is detected.

In another example, the metal detector may enter an ambient noise scanning mode to check whether there is a quieter operating frequency band than the band that it was operating in if the coil is not moving for a certain period of time, so that the metal detector may switch to the quieter operating frequency band as soon as a coil motion is detected.

In another example, fast or slow detection or discrimination filters may be selected if fast or slow coil motion is detected to optimize signal to noise ratio of a detection channel of a metal detector.

Therefore, it may be useful to detect the coil movement to optimize the performance of a metal detector. Coil motion detection is known to be achieved by using an accelerometer. However, it was found that the use of accelerometer would complicate hardware design and increase cost. Furthermore, accelerometer installed near a coil within the sensor head of the metal detector would require additional wires in a coil cable connecting the coil to the processing part of the metal detector. Further, the presence of an accelerometer may deteriorate detection performance of the metal detector due to the metallic components and/or the conductive loops in the circuits of the accelerometer. If the accelerometer is not installed near the coil within the sensor head, but in other places away from the sensor head, the metal detector may not detect coil motion properly in some circumstances.

The present disclosure offers an alternative, and does not require external motion sensor, such as an accelerometer for coil motion detection.

In one embodiment, it utilises a demodulated direct current (DC) or quasi DC channel (also known as a B channel) which is sensitive to the induced Electromotive Force (EMF) signal from movement of a search coil relative to the magnetic field of the earth. If the orientation of the coil is always maintained constant with respect to the magnetic field of the earth, there would be no signal detected in the demodulated DC or quasi DC channel. However, in practice, when a coil is swept, there is always accompanying small orientation variation which is sufficient to generate a motion signal in the demodulated DC or quasi DC channel (B channel). By assessment of the motion signal (movement signal) generated in the demodulated DC or quasi DC channel (B channel), a coil motion or movement may be detected. By conducting further analysis of the motion signal, e.g. by spectrum analysis or other methods, a coil sweep speed may be estimated.

By knowing the coil sweep speed in this way, the metal detector may operate on the optimum state based on user's swinging behaviour without using the external motion sensors. Benefits include, and not limited to, achieving simplicity (automation) and performance by tracking user's swinging behaviour without complicated hardware design. It may also be seen to be an elegant solution by utilizing a B channel which is a demodulated direct current (DC) or quasi DC channel to track user's swinging behaviour.

Note that a B channel is known. However, B channel is known and utilised to remove a sensitivity of a target channel to the movement of a search coil relative to the earth's magnetic field. Often, a target channel is a linear combination of one or more demodulated channels and a B channel. The coefficients of linear combination are selected such that target channel is insensitivity to the movement of a search coil relative to the earth's magnetic field. During the process to solve the coefficients of the linear combination, the residue of the target channel with respect to B channel is assessed, but the B channel itself is not assessed.

On the contrary, in accordance with the present disclosure, the B channel (which may or may not be the same B channel for the above stated function to solve the coefficients of the linear combination) is utilized and assessed in determining the motion or movement of the coil. For example, a receive signal is demodulated to produce a B channel among other channels. This B channel may be assessed to determine whether there is a coil movement. The B channel may also be assessed to determine the speed of the coil movement.

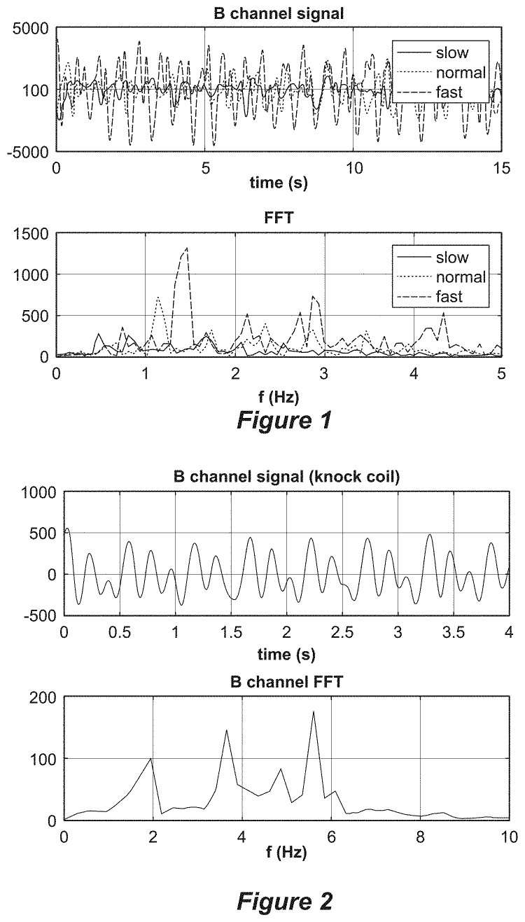

FIG. 1 shows responses of a B channel for different speeds of coil movement or coil sweep in both time domain and frequency domain. In particular, three different speeds of coil movement (coil sweep) which are slow, normal and fast in relative terms are shown in FIG. 1. The amplitude of B channel response for slow speed is much less (in time domain) than the amplitude of B channel response for fast speed. Similarly, the corresponding FFT of the B channel signal for fast moving metal detector shows different peaks which are higher in amplitudes and occurring at higher frequency, whereas the peaks in the FFT of slow moving metal detector are lower in amplitudes and occurring at lower frequency. Therefore, by analysing the FFT of the B channel signal coil motion is detected and/or coil sweep speed may be estimated.

FIG. 2 shows an exemplary B channel response due to a coil knock in both time domain and in frequency domain. The frequency domain response is the Fast Fourier Transform (FFT) of the time domain signal. As shown in FIG. 1, the peak in the FFT is below 2 Hz for a coil swing normally. However, the peak in the FFT for a coil knock may be above 5 Hz. A coil knock normally causes unwanted false alarms. Identifying a coil knock event can help to reduce or eliminate the corresponding false alarms. For example, audio can be muted as soon as a coil knock event is detected.

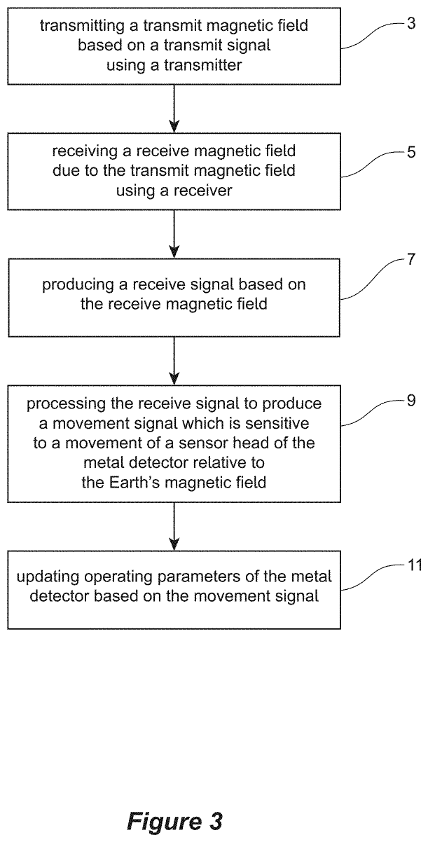

FIG. 3 depicts a general form of the present disclosure. In particular, it comprises several steps performed by a metal detector. Firstly, the step 3 of transmitting a transmit magnetic field based on a transmit signal using a transmitter is performed. In one embodiment, the transmitter is a conductive coil for transmitting magnetic field, and may take a form of a mono-loop coil, double D coil (DD coil), concentric coil, and other forms suitable for transmitting a magnetic field. The transmit magnetic field is generated by sending a transmit signal, sometimes known as transmit waveform, to the transmitter.

The next step 5 is the step of receiving a receive magnetic field due to the transmit magnetic field using a receiver. The receiver may be the same winding as the transmitter (for example, in the case of a mono-loop), or it may be different from the transmitter (for example, in the case of a DD coil).

The next step 7 is the step of producing a receive signal based on the receive magnetic field. Steps 3, 5, 7 are common steps of a metal detector in operation.

The step 9 comprises the inventive step of processing the receive signal to produce a movement signal which is sensitive to a movement of a sensor head of the metal detector relative to the Earth's magnetic field. This is different from the known and widely-used accelerometers with are dependent on Earth's gravity.

The term “sensitive to a movement of a sensor head” means that the movement signal varies with the movement of the sensor head relative to the magnetic field of the Earth. The Earth magnetic field, sometimes also known as geomagnetic field, is the magnetic field that extends from the Earth's interior out into space. As an approximation, it is represented by a field of a magnetic dipole currently tilted at an angle of about 11 degrees with respect to Earth's rotational axis, as if there were an enormous bar magnet placed at that angle through the centre of the Earth. The presence of the Earth magnetic field is detectable. The term “relative to” and “with respect to” are interchangeable in the context of this specification. The movement of the sensor head may be considered with respect to the Earth's magnetic field.

The receive signal may include a signal due to a movement of the metal detector relative to the magnetic field of the earth. It is this signal that is assessed to determine whether there is a coil movement. This signal may also be assessed to determine the speed of the coil movement.

If the orientation of the sensor head of the metal detector is always maintained constant with respect to the magnetic field of the earth, such as when the coil is not moved, there would be no variations in the receive signal. However, when the sensor head is moved, i.e., coil is swept, there is always accompanying small orientation variation in the receive signal which is processed in step 9 to produce a movement signal. Therefore, the movement signal is sensitive to the movement of the sensor head of the metal detector.

The next step 11 is the step of updating operating parameters of the metal detector based on the movement signal. For example, transmitting circuit could be turned off to save power if the sensor head is not moving for a certain period of time and be turned on as soon as the sensor head motion is detected.

In another example, the metal detector may enter an ambient noise scanning mode to check whether there is a quieter operating frequency band than the band that it was operating in if the coil is not moving for a certain period of time, so that the metal detector may switch to the quieter operating frequency band as soon as a coil motion is detected.

In another example, fast or slow detection or discrimination filters may be selected if fast or slow coil motion is detected to optimize signal to noise ratio of a detection channel of a metal detector.

In one embodiment, the receive signal is processed to produce a movement signal by demodulating the receive signal to produce a Direct Current (DC) or quasi DC channel (i.e. B channel) that is sensitive to the movement of the sensor head relative to the Earth's magnetic field, i.e., a DC or quasi DC channel is produced by demodulating the receive signal. The demodulation technique may be either analogue or digital. The movement signal may also be dependent on a ground channel (G channel) produced by demodulating the receive signal. As explained earlier, the receive signal itself comprises a signal due to the movement of the sensor head relative to the Earth's magnetic field, which is processed to produce the movement signal.

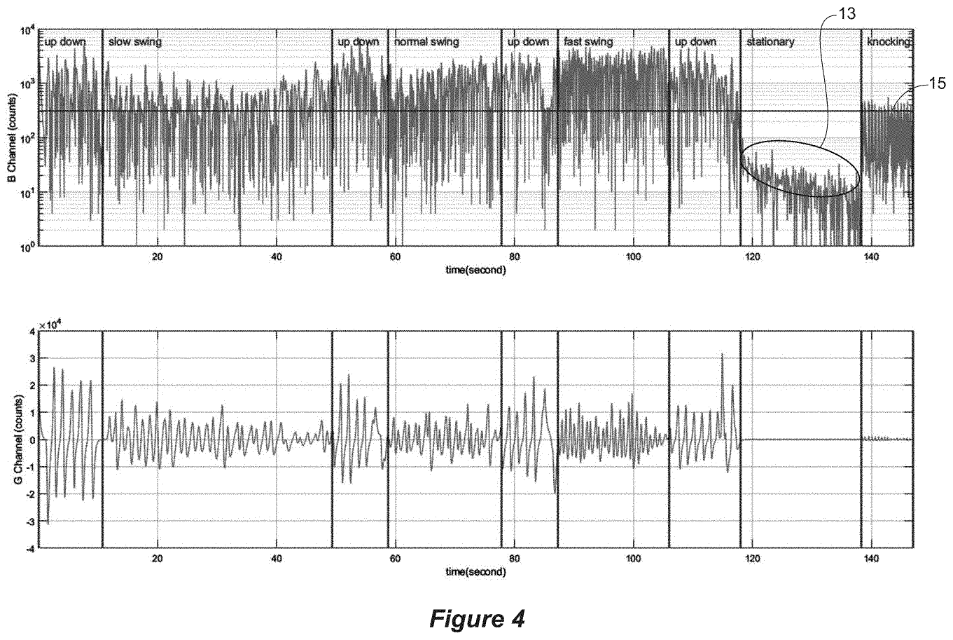

FIG. 4 presents a non-limiting working example of using a B channel to determine a movement of a coil. When the sensor head comprising the coil of the metal detector is moved, a signal is produced in the B channel (top part of FIG. 4). The B channel is produced by demodulating the receive signal of the metal detector to detect Earth magnetic field. A detector may be used to detect the B channel signal droop13. When the B channel signal droop 13 is below a threshold 15, it may be seen as an indicator that the coil is not moving. The threshold 15 of the B channel may be adjusted depending on application. Also shown in the FIG. 4 (bottom part of FIG. 4) is a G channel to detect the ground response. A G channel may be used to further confirm and verify the results of the B Channel. As can be seen, there is a certain relationship (though not conclusive by itself) between the G channel and the movement of the coil. For example, when the sensor head is moved in up-down direction, the G channel is with higher amplitudes, indicating high rate of change of the altitude position of the coil. On the other hand, when the sensor head is swept, the corresponding amplitudes of the G channel are low, indicating low rate of change of the altitude position of the coil. Similarly, when the metal detector is stationary, very low or nearly zero amplitude signal is shown in the corresponding G channel. Accordingly, by analysing the B channel, it can be determined whether there is any coil movement. Further, the movement speed may be determined. It is also possible to use a G channel to assist said determination.

By analysing the movement signal and by comparing it with the threshold signal, it is possible to determine whether the sensor head of the metal detector is stationary or in motion. Moreover, it is also possible to estimate whether the metal detector is moving fast, slow or normal. This has been discussed with reference to FIG. 2 which shows responses of B channel for different speeds in both time domain and frequency domain. In particular, 3 different coil sweep speeds which are slow, normal and fast are shown in FIG. 2. In one form, by analysing the spectrum, coil sweep speed can be estimated. By combining G channel, different types of coil movement can also be identified. As explained above, a coil up-down movement can be detected by analysing both G channel and B channel. A different signal processing function or parameter can be activated for different coil movement. For example, when a coil up-down movement is detected, fast tracking ground balance is triggered.

Once the movement signal is produced, the operating parameters of the metal detector may be updated based on the movement signal. The operating parameters comprise one or more of properties of the transmit signal or one or more of properties parameters used to process the receive signal, or both. In one form, the properties of the transmit signal comprises one or more of timings, amplitudes, frequency and phase of the transmit signal. For example, transmitting circuit could be turned off to save power if the sensor head is not moving for a certain period of time and be turned on as soon as the sensor head motion is detected Similarly, amplitude or phase of the transmit signal may be adjusted depending on the sweep speed of the metal detector.

The parameters used to process the receive signal comprises one or more of demodulation parameters and models for processing the receive signal. For example, fast/slow detection or discrimination filters could be selected if fast/slow sensor head motion is detected to optimize signal to noise ratio. Similarly, one or more demodulation parameters may be adjusted to optimize the performance of the metal detector.

In one form, the step of updating the operating parameters of the metal detector as mentioned above is performed automatically without user's intervention. For example, if it is detected that the sensor head is not moving for certain period of time, transmitting circuit could be turned off automatically without user's intervention. Similarly, when the sensor head motion is detected, transmitting circuit could be turned on automatically without user's intervention.

In another form, the step of updating the operating parameters requires a prior approval of a user of the metal detector. For example, if fast sensor head motion is detected, a prompt message will appear on user's screen asking for the permission to change the detection speed to fast and/or select a different discrimination filter accordingly. Once, the user approve the suggested update, the corresponding operating parameter will be updated accordingly. However, the user has a choice not to apply the suggested update, and to keep using the current operating parameter settings of the metal detector.

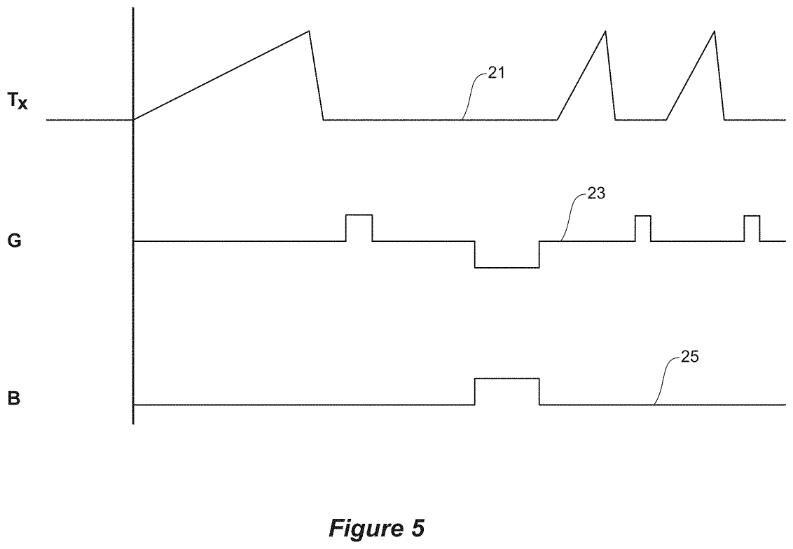

FIG. 5 shows exemplary demodulation functions for a B channel and a G channel with respect to a transmit signal used to generate transmit magnetic field for a pulse induction type of metal detector. In this example, the transmit signal 21 includes a ramp followed by two smaller ramps. The sequence then repeats. When the transmit signal 21 is zero, the metal detector receives a receive magnetic field due to the transmit magnetic field using a receiver and produces a receive signal based on the receive magnetic field. The receive signal is processed or demodulated to produce a G channel and a B channel besides one or more target channel. An exemplary function used to produce a G channel is shown as 23 and an exemplary function used to produce a B channel is shown as 25.

For continuous wave type of metal detector, as an example, G channel can be constructed by demodulating the receive signal at the same frequency of the transmitting waveform. As an example, B channel can be constructed by demodulating the receive signal at DC.

Those of skill in the art would understand that information and signals may be represented using any of a variety of technologies and techniques. For example, data, instructions, commands, information, signals, bits, symbols, and chips may be referenced throughout the above description and may be represented by voltages, currents, electromagnetic waves, magnetic fields or particles, optical fields or particles, or any combination thereof.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. For a hardware implementation, processing may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a combination thereof. Software modules, also known as computer programs, computer codes, or instructions, may contain a number of source code or object code segments or instructions, and may reside in any computer readable medium such as a RAM memory, flash memory, ROM memory, EPROM memory, registers, hard disk, a removable disk, a CD-ROM, a DVD-ROM or any other form of computer readable medium. In the alternative, the computer readable medium may be integral to the processor. The processor and the computer readable medium may reside in an ASIC or related device. The software codes may be stored in a memory unit and executed by a processor. The memory unit may be implemented within the processor or external to the processor, in which case it may be communicatively coupled to the processor via various means as is known in the art.

Throughout the specification and the claims that follow, unless the context requires otherwise, the words “comprise” and “include” and variations such as “comprising” and “including” will be understood to imply the inclusion of a stated integer or group of integers, but not the exclusion of any other integer or group of integers.

The reference to any prior art in this specification is not, and should not be taken as, an acknowledgment or any form of suggestion that such prior art forms part of the common general knowledge.

It will be appreciated by those skilled in the art that the invention is not restricted in its use to the particular application described. Neither is the present disclosure restricted in its preferred embodiment with regard to the particular elements and/or features described or depicted herein. It will be appreciated that the invention is not limited to the embodiment or embodiments disclosed, but is capable of numerous rearrangements, modifications and substitutions without departing from the scope of the invention as set forth and defined by the following claims.

1. A method to detect a target in a soil using a metal detector, the method comprising:
transmitting a transmit magnetic field based on a transmit signal using a transmitter;
receiving a receive magnetic field due to the transmit magnetic field using a receiver;
producing a receive signal based on the receive magnetic field;
processing the receive signal to produce a movement signal which is sensitive to a movement of a sensor head of the metal detector relative to the Earth's magnetic field; and
updating operating parameters of the metal detector based on the movement signal.

2. The method of claim 1, wherein the movement signal is produced by demodulating the receive signal to produce a Direct Current (DC) or quasi DC channel that is sensitive to the movement of the sensor head relative to the Earth's magnetic field.

3. The method of claim 2, wherein the movement signal is also dependent on a ground channel produced by demodulating the receive signal.

4. The method of claim 1, wherein the receive signal comprises an induced signal due to the movement of the sensor head relative to the Earth's magnetic field.

5. The method of claim 1, wherein the operating parameters comprise one or more of properties of the transmit signal or one or more of properties parameters used to process the receive signal, or both.

6. The method of claim 5, wherein the properties of the transmit signal comprises one or more of timings, amplitudes, frequency and phase of the transmit signal.

7. The method of claim 5, wherein the parameters used to process the receive signal comprises one or more of demodulation parameters and models for processing the receive signal.

8. The method of claim 1, wherein the step of updating the operating parameters is performed automatically without user's intervention.

9. The method of claim 1, wherein the step of updating the operating parameters requires a prior approval of a user of the metal detector.

10. A metal detector to detect a target in a soil, the metal detector comprising:
a transmitter for transmitting a transmit magnetic field based on a transmit signal;
a receiver for receiving a receive magnetic field due to the transmit magnetic field;
a processor for producing a receive signal based on the receive magnetic field; and for processing the receive signal to produce a movement signal which is sensitive to a movement of a sensor head of the metal detector relative to the Earth's magnetic field;
and for updating operating parameters of the metal detector based on the movement signal.

11. A non-transitory computer readable medium including instructions to perform the steps of claim 1.
